(19) United States
(12) Patent Application Publication
(10) Pub. No.: US 2024/0313737 A1
(43) Pub. Date: Sep. 19, 2024

(54) ACOUSTIC WAVE DEVICE

(71) Applicant: Murata Manufacturing Co., Ltd., Nagaokakyo-shi (JP)

(72) Inventor: Daisuke ITO, Nagaokakyo-shi (JP)

(21) Appl. No.: 18/659,492

(22) Filed: May 9, 2024

Related U.S. Application Data
(63) Continuation of application No. PCT/JP2022/041216, filed on Nov. 4, 2022.

(30) Foreign Application Priority Data
Nov. 18, 2021 (JP) 2021-187503

(51) Int. Cl. H03H 9/02; H03H 9/145; H03H 9/25

(52) U.S. Cl. CPC H03H 9/02992; H03H 9/02637; H03H 9/02834; H03H 9/02889; H03H 9/145; H03H 9/25

(57) ABSTRACT

An acoustic wave device includes a piezoelectric body layer having a crystal axis and an IDT electrode on the piezoelectric body layer. When an acoustic wave propagation direction is a first direction and an orthogonal or substantially orthogonal direction is a second direction, the crystal axis of the piezoelectric body layer is inclined in the second direction with respect to a thickness direction. The IDT electrode includes first and second busbars that oppose each other, and first and second electrode fingers and each including one end connected to any one of the first and second busbars. A region where the adjacent electrode fingers overlap each other in the first direction is a cross region which includes a central region positioned on a center side in the second direction, and first and second edge regions that oppose each other with the central region interposed therebetween in the second direction.

### CROSS REFERENCE TO RELATED APPLICATIONS

This application claims the benefit of priority to Japanese Patent Application No. 2021-187503, filed on Nov. 18, 2021, and is a Continuation Application of PCT Application No. PCT/JP2022/041216, filed on Nov. 4, 2022. The entire contents of each application are hereby incorporated herein by reference.

### BACKGROUND OF THE INVENTION

### 1. Field of the Invention

The present invention relates to acoustic wave devices.

### 2. Description of the Related Art

In the related art, acoustic wave devices are widely used as filters of mobile phones and the like. International Publication No. WO 2016/084526 discloses an example of an acoustic wave device. In the acoustic wave device, an interdigital transducer (IDT) electrode is provided on the piezoelectric film. The IDT electrode includes a pair of busbars and electrode fingers. Each of the busbars includes an inner busbar portion, an intermediate busbar portion, and an outer side portion busbar portion. Cavities are provided in the intermediate busbar portion along the acoustic wave propagation direction. On the other hand, a thick portion is provided on a distal end side of the electrode fingers. With these, the transverse mode ripple is reduced or prevented by configuring a plurality of regions having different acoustic velocities.

However, in the acoustic wave device of International Publication No. WO 2016/084526, the suppression of the inter-modulation distortion (IMD) was not sufficient. In a case where IMD occurs in the reception frequency band of the filter in which the acoustic wave device is used, it is difficult to isolate the IMD and the signal to be originally received. This leads to deterioration of reception sensitivity of mobile phones or the like.

### SUMMARY OF THE INVENTION

Example embodiments of the present invention provide acoustic wave devices each of which is able to reduce or prevent IMD.

An acoustic wave device according to an example embodiment of the present invention includes a piezoelectric body layer having a crystal axis, and an IDT electrode on the piezoelectric body layer, when an acoustic wave propagation direction is defined as a first direction and a direction orthogonal or substantially orthogonal to the first direction is defined as a second direction, the crystal axis of the piezoelectric body layer is inclined in the second direction with respect to a thickness direction of the piezoelectric body layer, the IDT electrode includes one pair of busbars opposing each other and electrode fingers including one end connected to any one of the pair of busbars, and among the electrode fingers, electrode fingers connected to one of the busbars and electrode fingers connected to another busbar are interdigitated with each other, a region where adjacent electrode fingers of the electrode fingers overlap each other in the first direction is a cross region, and the cross region includes a central region positioned on a central side in the second direction and one pair of edge regions opposing each other with the central region interposed therebetween in the second direction, when a dimension of the electrode finger along the first direction is defined as a width dimension, each of the electrode fingers includes a wide portion positioned in the pair of edge regions, the IDT electrode further includes one pair of gap regions positioned between the cross region and the pair of busbars, each of the pair of busbars includes cavities located along the first direction, each of the pair of busbars includes an outer side portion busbar portion and an inner busbar portion that oppose each other with the cavities interposed therebetween in the second direction, and connection portions that connect the outer side portion busbar portion and the inner busbar portion in each of the pair of busbars, and the inner busbar portion is positioned closer to a cross region side than the outer side portion busbar portion, and, when a region including a region where the one of the busbars is provided, one of the gap regions, and one of the edge regions is defined as a first region, and a region including a region where the other busbar is provided, the other gap region, and the other edge region is defined as a second region, the first region and the second region are asymmetric.

An acoustic wave device according to an example embodiment of the present invention includes a piezoelectric body layer having a crystal axis, and an IDT electrode on the piezoelectric body layer, when an acoustic wave propagation direction is defined as a first direction and a direction orthogonal or substantially orthogonal to the first direction is defined as a second direction, the crystal axis of the piezoelectric body layer is inclined in the second direction with respect to a thickness direction of the piezoelectric body layer, the IDT electrode includes one pair of busbars opposing each other, first electrode fingers each including one end connected to one of the busbars, and second electrode fingers each having one end connected to the other busbar, and the first electrode fingers and the second electrode fingers are interdigitated to each other, a region where one of the first electrode fingers and one of the second electrode fingers which are adjacent to each other overlap each other in the first direction is a cross region, and the cross region further includes a central region positioned on a central side in the second direction and one pair of edge regions that oppose each other with the central region interposed therebetween in the second direction, when a dimension of the one of the first electrode fingers and the one of the second electrode fingers along the first direction is defined as a width, each of the first electrode fingers and the second electrode fingers includes a wide portion positioned in the pair of edge regions, the IDT electrode further includes one pair of gap regions positioned between the cross region and the pair of busbars, each of the pair of busbars is provided with cavities located along the first direction, each of the pair of busbars is provided with an outer side portion busbar portion and an inner busbar portion that oppose each other with the cavities interposed therebetween in the second direction, and connection portions that connect the outer side portion busbar portion and the inner busbar portion in each of the pair of busbars, and the inner busbar portion is positioned closer to a cross region side than the outer side portion busbar portion, and when a region including a region where the one of the busbars is provided, one of the gap regions, and one of the edge regions is defined as a first region, and a region including a region where the other busbar is provided, the other gap region, and the other edge region is defined as a second region, an electrostatic capacitance defined by the connection portion, the inner busbar portion, at least some of the first electrode fingers, and the wide portion of the second electrode fingers in the first region, and an electrostatic capacitance generated by the connection portion, the inner busbar portion, at least some of the second electrode fingers, and the wide portion of the first electrode fingers in the second region are different from each other.

An acoustic wave device according to an example embodiment of the present invention includes a piezoelectric body layer having a crystal axis, and an IDT electrode on the piezoelectric body layer, the IDT electrode includes one pair of busbars opposing each other and electrode fingers each including one end connected to any one of the pair of busbars, and among the electrode fingers, electrode fingers connected to one of the busbars and electrode fingers connected to the other busbar are interdigitated to each other, when directions orthogonal to each other are defined as a first direction and a second direction, and the second direction is defined as the direction in which the electrode fingers extend, the crystal axis of the piezoelectric layer is inclined in the second direction with respect to a thickness direction of the piezoelectric body layer, a region where the electrode fingers adjacent to each other overlap each other in the first direction is a cross region, and the cross region includes a central region positioned on a central side in the second direction and one pair of edge regions that oppose each other with the central region interposed therebetween in the second direction, when a dimension of the electrode finger along the first direction is defined as a width, each of the electrode fingers includes a wide portion positioned in the pair of edge regions, the IDT electrode further includes one pair of gap regions positioned between the cross region and the pair of busbars, each of the pair of busbars is provided with cavities located along the first direction, each of the pair of busbars is provided with an outer side portion busbar portion and an inner busbar portion that oppose each other with the cavities interposed therebetween in the second direction, and connection portions that connect the outer side portion busbar portion and the inner busbar portion, and the inner busbar portion is positioned closer to the cross region side than the outer side portion busbar portion, a dielectric film provided to cover the IDT electrode is further provided on the piezoelectric body layer, and when a region configured with a region where the one of the busbars is provided, one of the gap regions, and one of the edge regions is defined as a first region, and a region configured with a region where the other busbar is provided, the other gap region, and the other edge region is defined as a second region, at least one of the following relationships 1) to 8) is different between the first region and the second region,
1) a dimension of each of the connection portions along the first direction in the one of the busbars and a dimension of each of the connection portions along the first direction in the other busbar,
2) a dimension of the connection portions along the second direction in the one of the busbars and a dimension of the connection portions along the second direction in the other busbar,
3) a pitch between the connection portions in the one of the busbars and a pitch between the connection portions in the other busbar,
4) a dimension of the inner busbar portion along the second direction in the one of the busbars and a dimension of the inner busbar portion along the second direction in the other busbar,
5) a dimension of the one of the gap regions along the second direction and a dimension of the other gap region along the second direction,
6) a width of the wide portion in the one of the edge regions and a width of the wide portion in the other edge region in the electrode fingers,
7) a thickness of the wide portion in the one of the edge regions and a thickness of the wide portion in the other edge region in the electrode fingers, and
8) a thickness of a part positioned in the one of the edge regions of the dielectric film and a thickness of a part positioned in the other edge region of the dielectric film.

With example embodiments of the present invention, an IMD can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic plan view showing an electrode structure of the IDT electrode of the first example embodiment of the present invention near a first busbar, near a second busbar, and near one of the reflectors.

FIG. 3 is a schematic cross-sectional view of the acoustic wave device according to the first example embodiment of the present invention taken along a second direction.

FIG. 4 is a diagram showing the intensity of 2HD in the first example embodiment of the present invention and a Comparative Example.

FIG. 5 is a diagram showing the intensity of 3HD in the first example embodiment of the present invention and the Comparative Example.

FIG. 6 is a schematic plan view showing an electrode structure of the IDT electrode of a second example embodiment of the present invention near the first busbar, near the second busbar, and near one of the reflectors.

FIG. 7 is a diagram showing the intensity of 3HD in the second example embodiment of the present invention and Comparative Example.

FIG. 8 is a schematic plan view showing an electrode structure of the IDT electrode of a third example embodiment of the present invention near the first busbar, near the second busbar, and near one of the reflectors.

FIG. 9 is a schematic plan view showing an electrode structure of the IDT electrode of a fourth example embodiment of the present invention near the first busbar, near the second busbar, and near one of the reflectors.

FIG. 10 is a schematic plan view showing an electrode structure of the IDT electrode of a fifth example embodiment of the present invention near the first busbar, near the second busbar, and near one of the reflectors.

FIG. 11 is a schematic plan view showing an electrode structure of the IDT electrode of a sixth example embodiment of the present invention near the first busbar, near the second busbar, and near one of the reflectors.

FIG. 12 is a schematic cross-sectional view of the acoustic wave device according to a seventh example embodiment of the present invention taken along a second direction.

FIG. 13 is a schematic cross-sectional view of the acoustic wave device according to an eighth example embodiment of the present invention taken along the second direction.

FIG. 14 is a schematic plan view showing an electrode structure of the IDT electrode of a ninth example embodiment of the present invention near the first busbar, near the second busbar, and near one of the reflectors.

FIG. 15 is a schematic plan view showing an electrode structure of the IDT electrode according to a modified example of the ninth example embodiment of the present invention near the first busbar, near the second busbar, and near one of the reflectors.

### DETAILED DESCRIPTION OF THE EXAMPLE EMBODIMENTS

Hereinafter, the present invention will be elucidated by describing example embodiments of the present invention with reference to the accompanying drawings.

Each example embodiment described in the present specification is an example, and partial replacement or combination of configurations is possible between different example embodiments.

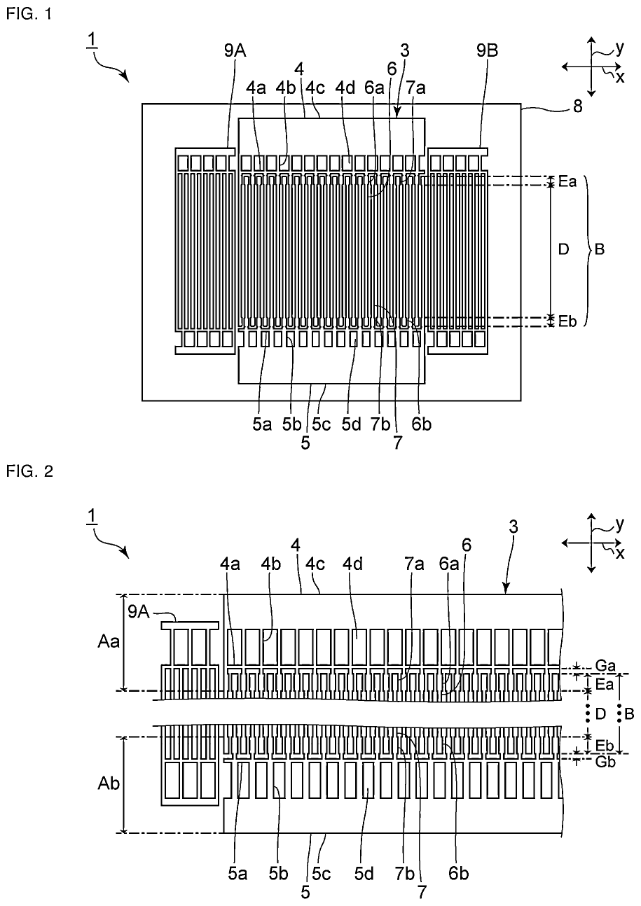

FIG. 1 is a schematic plan view of an acoustic wave device according to a first example embodiment of the present invention. In FIG. 1, a dielectric film to be described later is omitted. The same applies to the other schematic plan views.

The acoustic wave device 1 includes a piezoelectric substrate. In present the example embodiment, the piezoelectric substrate includes only the piezoelectric body layer 8. Specifically, the piezoelectric body layer 8 is made of lithium niobate, for example. More specifically, the piezoelectric body layer 8 is made of, for example, LiNbO₃ having Y-Cut 120°. In the present specification, a case where a certain member is made of a certain material includes a case where a trace amount of an impurity that does not deteriorate electrical characteristics of the acoustic wave device is included. The cut-angles and the material of the piezoelectric body layer 8 are not limited to the above. As the material of the piezoelectric body layer 8, for example, lithium tantalate such as LiTaO₃ can also be used. The piezoelectric substrate may be a laminated substrate including the piezoelectric body layer 8.

An IDT electrode 3 is provided on the piezoelectric body layer 8. An acoustic wave is excited by applying an AC voltage to the IDT electrode 3. Hereinafter, the acoustic wave propagation direction is defined as a first direction x, and a direction orthogonal or substantially orthogonal to the first direction x is defined as a second direction y. On both sides of the IDT electrode 3 in the first direction x on the piezoelectric body layer 8, one pair of reflectors 9A and one pair of reflectors 9B are provided. The acoustic wave device 1 according to the present example embodiment is, for example, an elastic surface acoustic wave resonator. However, the acoustic wave device according to the present invention may be, for example, a filter device or a multiplexer having a plurality of acoustic wave resonators.

Further, the piezoelectric body layer 8 has a crystal axis. A crystal axis of the piezoelectric body layer 8 is inclined in the second direction y with respect to the thickness direction of the piezoelectric body layer 8.

The IDT electrode 3 preferably includes a first busbar 4 and a second busbar 5 as a pair of busbars, and first electrode fingers 6 and second electrode fingers 7. The first busbar 4 and the second busbar 5 oppose each other. Ends of the first electrode fingers 6 are respectively connected to the first busbar 4. Ends of the second electrode fingers 7 are respectively connected to the second busbar 5. The first electrode fingers 6 and the second electrode fingers 7 are interdigitated with each other. Hereinafter, the first electrode finger 6 and the second electrode finger 7 may be simply referred to as an electrode finger. In the present example embodiment, the second direction y is preferably parallel or substantially parallel to a direction in which the electrode fingers extend.

The IDT electrode 3, the reflector 9A, and the reflector 9B preferably include, for example, a Pt layer and an AlCu layer. Specifically, a Pt layer is provided on the piezoelectric body layer 8. An AlCu layer is provided on the Pt layer. However, the materials of the IDT electrode 3, the reflector 9A, and the reflector 9B are not limited to the above. Alternatively, the IDT electrode 3, the reflector 9A, and the reflector 9B may include a single-layer metal film.

When the IDT electrode 3 is viewed from the first direction x, a region where the adjacent electrode fingers overlap each other is a cross region B. The cross region B includes a central region D and a first edge region Ea and a second edge region Eb as one pair of edge regions. The central region D is positioned on the center side in the cross region B in the second direction y. The first edge region Ea and the second edge region Eb oppose each other with the central region D interposed therebetween in the second direction y.

FIG. 2 is a schematic plan view showing an electrode structure of the IDT electrode of the first example embodiment near the first busbar, near the second busbar, and near one of the reflectors.

In the first edge region Ea, the first electrode fingers 6 preferably include wide portions 6a, and the second electrode fingers 7 preferably include wide portions 7a. In the second edge region Eb, the first electrode fingers 6 include wide portions 6b, and the second electrode fingers 7 include wide portions 7b. Here, the width of the electrode finger is a dimension along the first direction x of the electrode finger. A width of the electrode finger in each wide portion is wider than a width of the electrode finger in the central region D.

The IDT electrode 3 preferably includes a first gap region Ga and a second gap region Gb as a pair of gap regions. The first gap region Ga is positioned between the cross region B and the first busbar 4. The second gap region Gb is positioned between the cross region B and the second busbar 5.

Cavities 4d are preferably provided in the first busbar 4 of the IDT electrode 3 along the first direction x. More specifically, the first busbar 4 includes an inner busbar portion 4a, connection portions 4b, and an outer side portion busbar portion 4c. The inner busbar portion 4a and the outer side portion busbar portion 4c oppose each other with the cavity 4d interposed therebetween in the second direction y. The inner busbar portion 4a is positioned on the cross region B side with respect to the outer side portion busbar portion 4c. The inner busbar portion 4a and the outer side portion busbar portion 4c are connected to each other by the connection portions 4b. The connection portions 4b extend parallel or substantially parallel to the second direction y. The cavities 4d are cavities surrounded by the inner busbar portion 4a, the connection portions 4b, and the outer side portion busbar portion 4c. In addition, each connection portion 4b is provided on the extension line of each first electrode finger 6 and is not provided on the extension line of each second electrode finger 7. It should be noted that the disposition of the connection portions 4b is not limited to the above.

The second busbar 5 is also configured in the same or substantially the same manner as the first busbar 4. Cavities 5d are preferably provided in the second busbar 5 along the first direction x. The second busbar 5 includes an inner busbar portion 5a, connection portions 5b, and an outer side portion busbar portion 5c.

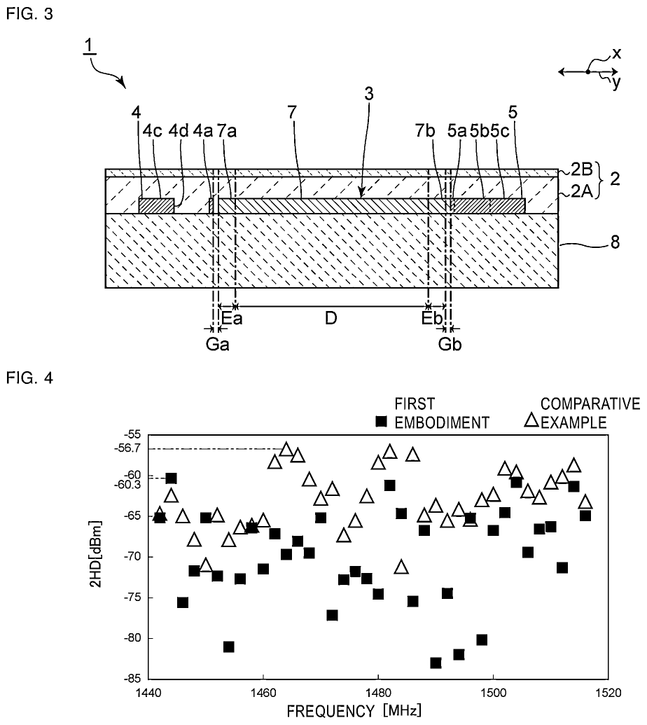

FIG. 3 is a schematic cross-sectional view of the acoustic wave device according to the first example embodiment taken along the second direction. Here, the broken line in FIG. 3 shows a boundary of each portion of the second busbar 5. The same applies to the other schematic cross-sectional views.

The dielectric film 2 is provided on the piezoelectric body layer 8 to cover the IDT electrode 3. In the present example embodiment, the dielectric film 2 is preferably a laminate film of, for example, a silicon oxide layer 2A and a silicon nitride layer 2B. More specifically, the silicon oxide layer 2A is provided on the piezoelectric body layer 8. The silicon nitride layer 2B is provided on the silicon oxide layer 2A. The dielectric film 2 is provided such that the IDT electrode 3 is less likely to be damaged. Further, in a case where the dielectric film 2 includes the silicon oxide layer 2A, an absolute value of a temperature coefficient of frequency (TCF) of the acoustic wave device 1 can be reduced, and the frequency temperature characteristics can be improved. In addition, by providing the silicon nitride layer 2B on the silicon oxide layer 2A, the moisture resistance can be improved. The material of the dielectric film 2 is not limited to the above. The dielectric film 2 may be a single-layer dielectric film. Note that the dielectric film 2 does not necessarily need to be provided and can be omitted if so desired.

Hereinafter, a region including the region where the first busbar 4 is provided, the first gap region Ga, and the first edge region Ea is defined as a first region Aa. A region including the region where the second busbar 5 is provided, the second gap region Gb, and the second edge region Eb is defined as a second region Ab.

A feature of the present example embodiment is that the crystal axis of the piezoelectric body layer 8 is inclined in the second direction y with respect to the thickness direction of the piezoelectric body layer 8, and the configuration of the first region Aa and the configuration of the second region Ab are asymmetric. The term “asymmetrically configured” means that the thickness, the dimension, the spacing, or the like of the portion in the IDT electrode 3 or the thickness of the dielectric film 2 is different between the first region Aa and the second region Ab. The thickness and the dimension of the portion in the IDT electrode 3 are, for example, the thickness or the dimension of the first busbar 4 and the second busbar 5, or the thickness or the dimension of the wide portion 6a and the wide portion 6b of the first electrode finger 6 and the wide portion 7a and the wide portion 7b of the second electrode finger 7. The interval between the portions in the IDT electrode 3 is a pitch between the connection portions of the busbar, an interval between the distal end of the electrode finger and the busbar, or the like.

In the present example embodiment, as shown in FIG. 2, the dimension of each of the connection portions 4b in the first busbar 4 along the first direction x is preferably different from the dimension of each of the connection portions 5b in the second busbar 5 along the first direction x. As a result, the configuration of the first region Aa and the configuration of the second region Ab are asymmetric. As a result, the IMD can be reduced or prevented. The details of this advantageous effect will be described below by comparing the first example embodiment and Comparative Example.

Comparative Example is different from the first example embodiment in that the configuration of the first region and the configuration of the second region are symmetric. In the acoustic wave device having the configuration of the first example embodiment and the acoustic wave device of Comparative Example, the IMD was measured. Specifically, an LTE electric signal of 721 to about 758 MHz at about 28 dBm was applied to the first busbar side in each acoustic wave device. In this case, the intensity of the IMD occurred on the second busbar side was measured. More specifically, the intensity of the second harmonic distortion (2HD) generated at about 1430 MHz to about 1520 MHz and the intensity of the third harmonic distortion (3HD) generated at about 2140 MHz to about 2320 MHz were measured.

Structural parameters of the acoustic wave device having the configuration of the first example embodiment are as follows. Here, a wavelength defined by the electrode finger pitch of the IDT electrode is defined as A. The electrode finger pitch is a distance between centers of adjacent electrode fingers in the first direction x. A dimension of the cross region B along the second direction y is defined as a cross width. A dimension of the wide portion along the second direction y is defined as a length of the wide portion. A dimension of the inner busbar portion along the second direction y is defined as a width of the inner busbar portion. A dimension of the gap region along the second direction y is defined as a width of the gap region. A dimension of the connection portion along the second direction y is defined as a length of the connection portion. A dimension of the connection portion along the first direction x is defined as a width of the connection portion.

Piezoelectric body layer: material . . . Y-Cut 120° LiNbO₃

Dielectric film: layer configuration . . . SiO₂ layer/SiN layer from the piezoelectric body layer side; thickness . . . about 1200 nm/about 40 nm from the piezoelectric body layer side

IDT electrode: layer configuration . . . Pt layer/AlCu layer from the piezoelectric body layer side, a weight ratio of Cu in the AlCu layer . . . about 10% by weight, thickness . . . about 345 nm/275 nm from the piezoelectric body layer side
Wavelength λ: about 4 μm
Cross width: about 80 μm
Number of electrode fingers: 121

First region: length of wide portion . . . about 2.119 μm, width of wide portion . . . about 1.38 μm, width of inner busbar portion . . . about 0.7 μm, width of first gap region . . . about 0.61 μm, length of connection portion . . . about 5 μm, width of connection portion . . . about 0.98 μm

Second region: length of wide portion . . . about 2.119 μm, width of wide portion . . . about 1.38 μm, width of inner busbar portion . . . about 0.7 μm, width of second gap region . . . about 0.61 μm, length of connection portion about 5 μm, width of connection portion . . . about 1.96 μm

The structural parameters of the acoustic wave device of Comparative Example are the same or substantially the same as the design parameters of the acoustic wave device of the first example embodiment, except that the width of the connection portion in the second region is about 0.98 μm.

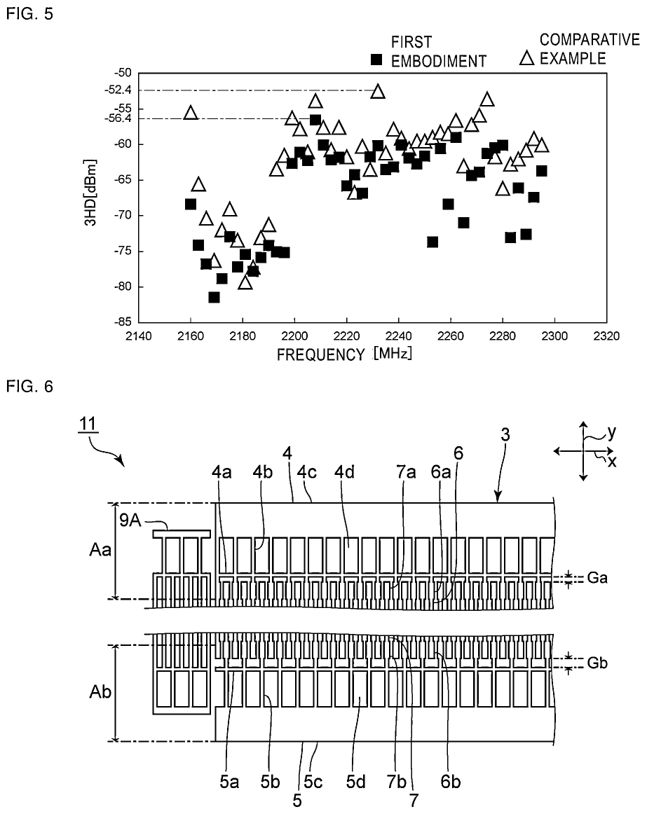

FIG. 4 is a diagram showing the intensity of the 2HD in the first example embodiment and Comparative Example. FIG. 5 is a diagram showing the intensity of the 3HD in the first example embodiment and Comparative Example.

As shown in FIG. 4, in Comparative Example, the minimum value of the absolute value of the intensity in the 2HD is about-56.7 dBm. On the other hand, in the first example embodiment, the minimum value of the absolute value of the intensity in the 2HD is about-60.3 dBm. Therefore, in the first example embodiment, the intensity of the 2HD is improved by about 3.6 dBm as compared with Comparative Example. As shown in FIG. 5, in Comparative Example, the minimum value of the absolute value of the intensity in the 3HD is about −52.4 dBm. On the other hand, in the first example embodiment, the minimum value of the absolute value of the intensity in the 3HD is about-56.4 dBm. Therefore, in the first example embodiment, the intensity of the 3HD is improved by about 4 dBm as compared with Comparative Example. As described above, in the first example embodiment, the IMD is reduce or prevented.

The IMD is generated by the fact that the intensity of the electric field in the first region and the intensity of the electric field in the second region are not the same. In Comparative Example, the configurations of the first region and the second region are symmetric. However, in Comparative Example, as in the first example embodiment, the crystal axes of the piezoelectric body layers were inclined in the second direction with respect to the thickness direction of the piezoelectric body layer. In this case, a component in a second direction on the polarization axis of the piezoelectric body layer is asymmetric in the first region and the second region. Therefore, when a certain electrical signal is applied to the acoustic wave device, the intensity of the electric field in the first region and the intensity of the electric field in the second region are not the same, and IMD occurs.

On the other hand, in the first example embodiment shown in FIG. 2, the configuration of the first region Aa and the configuration of the second region Ab are asymmetric. The electric field in the first region Aa is affected by the electrostatic capacitance in the first region Aa and the component of the polarization axis of the piezoelectric body layer 8 in the second direction y. The electric field in the second region Ab is affected by the electrostatic capacitance in the second region Ab and the component of the polarization axis of the piezoelectric body layer 8 in the second direction y. In the first example embodiment, the electrostatic capacitance in the first region Aa is mainly the electrostatic capacitance between the plurality of wide portions 7a of the second electrode fingers 7 and the inner busbar portion 4a and the connection portion 4b of the first busbar 4 and the wide portions 6a of the first electrode fingers 6. On the other hand, the electrostatic capacitance in the second region Ab is mainly an electrostatic capacitance between the wide portions 6b of the first electrode fingers 6 and the inner busbar portion 5a and the connection portions 5b of the second busbar 5 and the wide portions 7b of the second electrode fingers 7.

Here, the inner busbar portion 4a is located between the connection portion 4b of the first busbar 4 and the wide portion 7a of the second electrode finger 7. However, as is clear from the fact that the electric field line used to indicate the electric field or the electrostatic capacitance includes a line extending in an arc shape as well as a straight line, the electrostatic capacitance is also generated between the connection portion 4b and the wide portion 7a. The same applies to a part between the connection portion 5b of the second busbar 5 and the wide portion 6b of the first electrode finger 6. The electrostatic capacitance between the connection portion 4b and the wide portion 7a and the electrostatic capacitance between the connection portion 5b and the wide portion 6b are strictly complicated, but will be described in a simplified manner to the extent that the members have a correlation.

The electrostatic capacitance of the capacitor is represented by C=εS/d when the electrostatic capacitance is defined as C, the dielectric constant is defined as &, the area of the electrode plate is defined as S, and the distance between the electrode plates is defined as d. However, the configuration of the first region Aa, such as the connection portion 4b and the wide portion 6a, is not a configuration in which the simple electrode plates oppose each other. In the first region Aa, the areas of the portions corresponding to the pair of electrode plates are different from each other. In this case, when an area of a portion corresponding to one electrode plate is defined as S1 and an area of a portion corresponding to the other electrode plate is defined as S2, the electrostatic capacitance C can be represented by C˜(S1×S2)/d. The same applies to the second region Ab.

For example, the area S1 is defined as the area of the cross section of the connection portion 4b of the first busbar 4 along the second direction y, and the area S2 is defined as the area of the end surface of the distal end of the wide portion 7a of the second electrode finger 7. For example, the distance d is a distance between the center of a portion of the connection portion 4b opposing the cavity 4d and the center of an end surface of the distal end of the wide portion 7a. In this case, the electrostatic capacitance C between the connection portion 4b and the wide portion 7a is larger as the product of the area S1 and the area S2 is larger, and is larger as the distance d is shorter. In addition, the wider the width of the connection portion 4b, the shorter the distance d. Therefore, the electrostatic capacitance C is larger as the width of the connection portion 4b is larger, and the electrostatic capacitance of the entire first region Aa is also larger. The same applies to the second region Ab.

In the first example embodiment, the width of the connection portions 4b in the first busbar 4 is different from the width of the connection portions 5b in the second busbar 5. Therefore, the electrostatic capacitance in the first region Aa and the electrostatic capacitance in the second region Ab are different from each other. In addition, the crystal axis of the piezoelectric body layer 8 is inclined in a second direction y with respect to the thickness direction of the piezoelectric body layer 8. As a result, the intensities of the electric field in the first region Aa and the electric field in the second region Ab can be made close to each other. Therefore, the IMD can be reduced or prevented.

When the acoustic wave device is used in a mobile phone or the like, the IMD such as 2HD or 3HD becomes an interference wave. It is difficult to isolate these interference waves from the signal to be received. On the other hand, in a case where the acoustic wave device according to the present invention is used in a mobile phone or the like, the IMD is reduced or prevented. Therefore, it is possible to increase the reception sensitivity of the mobile phone or the like.

Meanwhile, in the first example embodiment, the pair of low acoustic velocity regions are preferably configured by providing the wide portion on the electrode fingers in the pair of edge regions. One of the pair of low acoustic velocity regions in the first example embodiment is a region extending across the region where the first edge region Ea, the first gap region Ga, and the inner busbar portion 4a in the first busbar 4 are provided. The other low acoustic velocity region is a region extending across the region where the second edge region Eb, the second gap region Gb, and the inner busbar portion 5a in the second busbar 5 are provided. In addition, the low acoustic velocity region is a region where the acoustic velocity or the average acoustic velocity is lower than the acoustic velocity in the central region D. More specifically, the wide portion 6a of the first electrode finger 6 and the wide portion 7a of the second electrode finger 7 are provided, and accordingly, the acoustic velocity is lowered in the first edge region Ea. As a result, the average acoustic velocity in the region where the first edge region Ea, the first gap region Ga, and the inner busbar portion 4a in the first busbar 4 are provided is lowered. Similarly, the wide portion 6b of the first electrode finger 6 and the wide portion 7b of the second electrode finger 7 are provided, and accordingly, the average acoustic velocity is lowered in the region where the second edge region Eb, the second gap region Gb, and the inner busbar portion 5a in the second busbar 5. As a result, one pair of low acoustic velocity regions is configured.

On the other hand, in a region of the first busbar 4 where the cavities 4d are provided, each connection portion 4b is preferably provided on the extension line of each first electrode finger 6, and not provided on the extension line of each second electrode finger 7. As a result, a high acoustic velocity region is configured in the region. The high acoustic velocity region is a region where the acoustic velocity is higher than the acoustic velocity in the central region D. Similarly, in a region of the second busbar 5 where the cavities 5d are provided, the high acoustic velocity region is configured. In the first example embodiment, in the second direction y, the central region D, one pair of the low acoustic velocity regions, and one pair of the high acoustic velocity regions are located in this order. As a result, the transverse mode is established, and the transverse mode can be reduced or prevented.

In the first example embodiment, the widths of all of the connection portions 4b in the first busbar 4 and the widths of all of the connection portions 5b in the second busbar 5 are preferably different from each other. However, for example, the width of at least one connection portion 4b in the first busbar 4 and the width of at least one connection portion 5b in the second busbar 5 may be different from each other. In this case as well, the electrostatic capacitance in the first region Aa and the electrostatic capacitance in the second region Ab can be made different from each other. Therefore, the intensities of the electric field in the first region Aa and the electric field in the second region Ab can be made close to each other, and the IMD can be reduced or prevented.

As a modified example of the first example embodiment, for example, the thicknesses of the connection portions 4b in the first busbar 4 and the thicknesses of the connection portions 5b in the second busbar 5 may be different from each other. As a result, the configuration of the first region Aa and the configuration of the second region Ab may be asymmetric. In this case as well, the IMD can be reduced or prevented as in the first example embodiment.

FIG. 6 is a schematic plan view showing an electrode structure of the IDT electrode of the second example embodiment near the first busbar, near the second busbar, and near one of the reflectors.

The present example embodiment is different from the first example embodiment in that the dimension of the first gap region Ga along the second direction y and the dimension of the second gap region Gb along the second direction y are different from each other. That is, the width of the first gap region Ga and the width of the second gap region Gb are different from each other. The present example embodiment is different from the first example embodiment also in that the widths of the connection portions 4b in the first busbar 4 and the widths of the connection portions 5b in the second busbar 5 are the same or substantially the same. The acoustic wave device 11 of the present example embodiment preferably has the same or substantially the same configuration as the acoustic wave device 1 of the first example embodiment in other respects than the above.

In the acoustic wave device 11, the width of the first gap region Ga and the width of the second gap region Gb are different from each other, and accordingly, the configuration of the first region Aa and the configuration of the second region Ab are asymmetric. As a result, the IMD can be reduced or prevented. The details of this effect will be shown below by comparing the second example embodiment and Comparative Example.

Comparative Example is the same or substantially the same as Comparative Example compared with the first example embodiment in FIGS. 4 and 5. That is, Comparative Example is different from the second example embodiment in that the configuration of the first region and the configuration of the second region are symmetric. In the acoustic wave device according to the second example embodiment and the acoustic wave device of Comparative Example, the IMD was measured. More specifically, the intensity of the 3HD was measured.

The design parameters of the acoustic device having the configuration of the second example embodiment are the same or substantially the same as the design parameters of the acoustic wave device of the first example embodiment according to the comparison of FIGS. 4 and 5, except that the width of the connection portion of the second busbar and the width of the second gap region are different. More specifically, the width of the connection portion of the second busbar is the same or substantially the same as the width of the connection portion of the first busbar, which is, for example, about 0.98 μm. The width of the second gap region is, for example, about 0.7 μm. On the other hand, the width of the first gap region is, for example, about 0.61 μm. On the other hand, in Comparative Examples, the width of the first gap region and the width of the second gap region were, for example, about 0.61 μm.

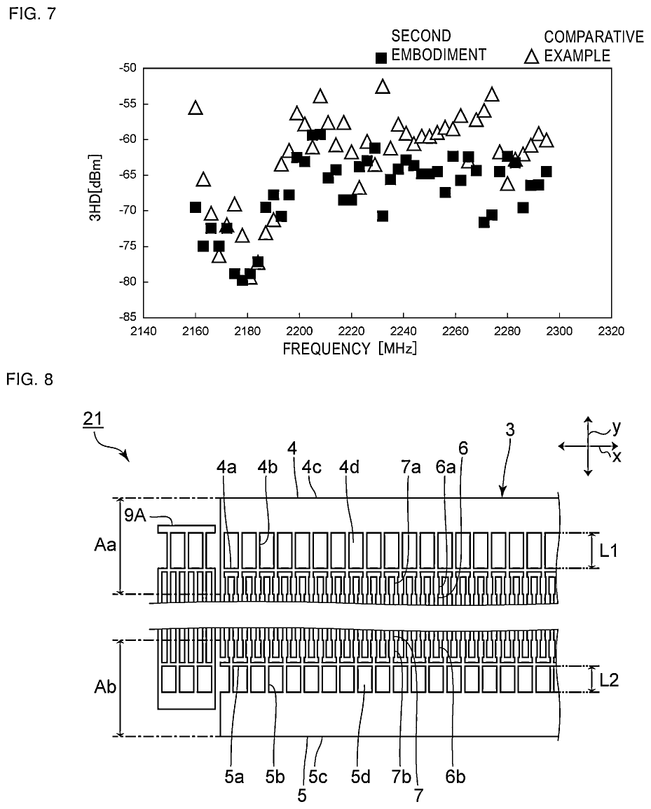

FIG. 7 is a diagram showing the intensity of the 3HD in the second example embodiment and Comparative Example.

As shown in FIG. 7, in the second example embodiment, it can be seen that the 3HD is reduced or prevented more than in Comparative Examples. In the second example embodiment shown in FIG. 6, the width of the first gap region Ga and the width of the second gap region Gb are different from each other, and accordingly, the electrostatic capacitance of the first region Aa and the electrostatic capacitance of the second region Ab are different from each other. Further, since the crystal axis of the piezoelectric body layer 8 is inclined in the second direction y with respect to the thickness direction of the piezoelectric body layer 8, the intensity of the electric field in the first region Aa and the intensity of the electric field in the second region Ab can be brought close to each other. Therefore, the IMD can be reduced or prevented.

Hereinafter, third to eighth example embodiments will be described. In the third to eighth example embodiments, the crystal axis of the piezoelectric body layer 8 is preferably inclined in the second direction y with respect to the thickness direction, and the configuration of the first region Aa and the configuration of the second region Ab are preferably asymmetric. As a result, in the third to eighth example embodiments as well, the IMD can be reduced or prevented in the same manner as in the first example embodiment and the second example embodiment.

Any of the third to eighth example embodiments is different from the first example embodiment also in that the width of the connection portions 4b in the first busbar 4 and the width of the connection portions 5b in the second busbar 5 are the same or substantially the same. In addition, in any of the third to eighth example embodiments, the configuration is different from the first example embodiment, and the configuration of the first region Aa and the configuration of the second region Ab are asymmetric. In addition to the above point, the acoustic wave device according to the third to eighth example embodiments has the same or substantially the same configuration as the acoustic wave device 1 according to the first example embodiment.

In the third example embodiment shown in FIG. 8, the dimensions of the connection portions 4b in the first busbar 4 along the second direction y and the dimensions of the connection portions 5b in the second busbar 5 along the second direction y are preferably different from each other. That is, a length L1 of the connection portions 4b and a length L2 of the connection portions 5b are different from each other. As a result, in the acoustic wave device 21, the configuration of the first region Aa and the configuration of the second region Ab are asymmetric.

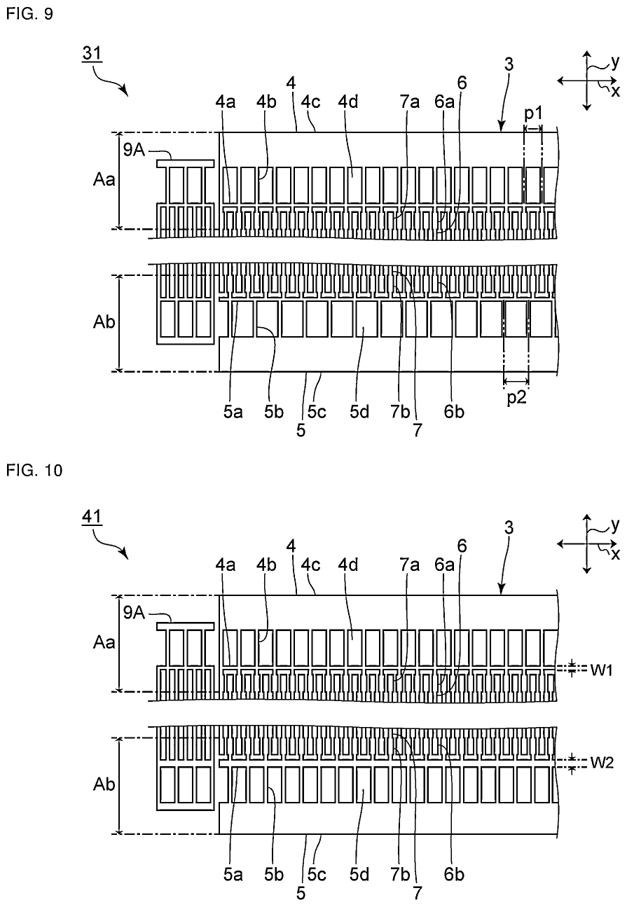

In the fourth example embodiment shown in FIG. 9, pitches p1 of the connection portions 4b in the first busbar 4 and pitches p2 of the connection portions 5b in the second busbar 5 are preferably different from each other. The pitch of the connection portion is a distance between the centers of the adjacent connection portions in the first direction x. As a result, in the acoustic wave device 31, the configuration of the first region Aa and the configuration of the second region Ab are asymmetric.

In the fifth example embodiment shown in FIG. 10, the dimension of the inner busbar portion 4a in the first busbar 4 along the second direction y and the dimension of the inner busbar portion 5a in the second busbar 5 along the second direction y are preferably different from each other. That is, the width W1 of the inner busbar portion 4a and the width W2 of the inner busbar portion 5a are different from each other. As a result, in the acoustic wave device 41, the configuration of the first region Aa and the configuration of the second region Ab are asymmetric.

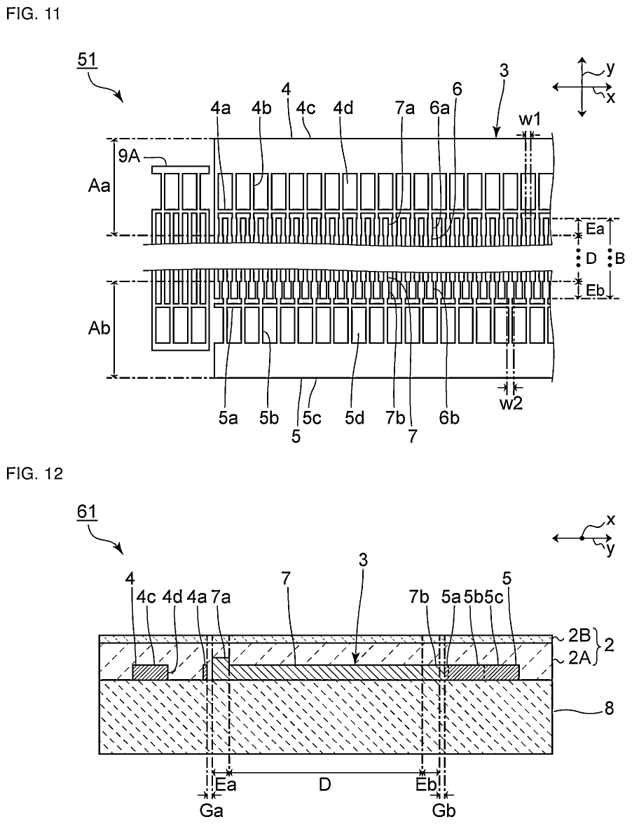

In the sixth example embodiment shown in FIG. 11, a width w1 of the wide portion of the electrode fingers in the first edge region Ea and a width w2 of the wide portion of the electrode fingers in the second edge region Eb are preferably different from each other. As a result, in the acoustic wave device 51, the configuration of the first region Aa and the configuration of the second region Ab are asymmetric. In the present example embodiment, the width w1 of the wide portion of all the electrode fingers in the first edge region Ea and the width w2 of the wide portion of all the electrode fingers in the second edge region Eb are preferably different from each other. However, the width w1 of the wide portion of the at least one electrode finger in the first edge region Ea and the width w2 of the wide portion of the at least one electrode finger in the second edge region Eb may be different from each other.

In the seventh example embodiment shown in FIG. 12, the thicknesses of the wide portions of the electrode fingers in the first edge region Ea and the thicknesses of the wide portions of the electrode fingers in the second edge region Eb are preferably different from each other. As a result, in the acoustic wave device 61, the configuration of the first region Aa and the configuration of the second region Ab are asymmetric. In the present example embodiment, the thickness of the wide portion of all the electrode fingers in the first edge region Ea and the thickness of the wide portion of all the electrode fingers in the second edge region Eb are different from each other. However, the thickness of the wide portion of the at least one electrode finger in the first edge region Ea and the thickness of the wide portion of the at least one electrode finger in the second edge region Eb may be different from each other.

Meanwhile, in example embodiments of the present invention, the configuration of the first region Aa and the configuration of the second region Ab are asymmetric. The configuration of the first region Aa described in the first to seventh example embodiments and the modified example of the first example embodiment is at least a portion of the connection portion 4b, the inner busbar portion 4a, and the first electrode fingers 6, and at least a portion of the wide portions 7a of the second electrode fingers 7 in the first region Aa. At least a portion of the configuration of the second region Ab is at least a portion of the connection portion 5b, the inner busbar portion 5a, and the second electrode fingers 7, and at least a portion of the wide portions 6b of the first electrode fingers 6 in the second region Ab.

In such a case, example embodiments of the present invention are characterized in that the following electrostatic capacities are different from each other. The other electrostatic capacitance is an electrostatic capacitance formed by the connection portion 4b, the inner busbar portion 4a, at least some of the first electrode fingers 6, and the wide portions 7a of the second electrode fingers 7 in the first region Aa. The other electrostatic capacitance is an electrostatic capacitance formed by the connection portion 5b, the inner busbar portion 5a, at least some of the second electrode fingers 7, and the wide portions 6b of the first electrode fingers 6 in the second region Ab.

However, the configuration of the first region Aa, which is asymmetric, and the configuration of the second region Ab are not limited to the above. As a modified example of the seventh example embodiment, for example, a mass addition film may be provided on at least one wide portion of the electrode finger in one edge region, and a mass addition film is not necessarily provided on the wide portion of the electrode finger in the other edge region. As a result, the configuration of the first region Aa and the configuration of the second region Ab may be asymmetric. In any case, the mass addition film may be provided on the wide portion of at least one electrode finger in both edge regions, and the thickness of the mass addition film in both edge regions may be different from each other. As a result, the configuration of the first region Aa and the configuration of the second region Ab may be asymmetric. The mass addition film may be provided on the main surface of the electrode finger on the piezoelectric body layer 8 side, or may be provided on the main surface opposing the main surface. As the mass addition film, an appropriate metal or dielectric can be used.

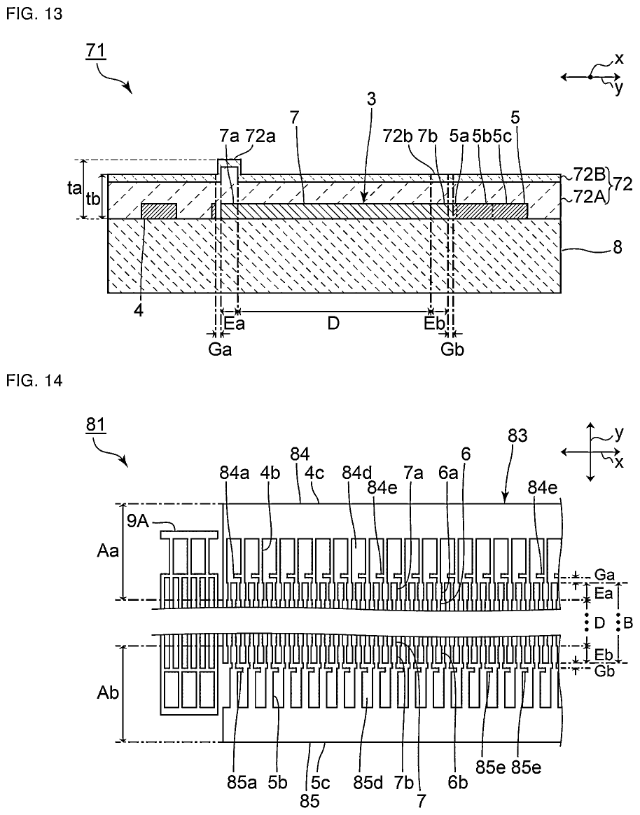

In the eighth example embodiment shown in FIG. 13, a thickness ta of the first portion 72a positioned in the first edge region Ea in the dielectric film 72 and a thickness tb of the second portion 72b positioned in the second edge region Eb in the dielectric film 72 are different from each other. As a result, in the acoustic wave device 71, the configuration of the first region Aa and the configuration of the second region Ab are asymmetric. In addition, the thickness of the dielectric film 72 is defined as a distance between a surface of the dielectric film 72 opposing a surface in contact with the piezoelectric body layer 8 and a main surface in contact with the dielectric film 72 in the piezoelectric body layer 8.

As described above, the plurality of electric field lines in the electric field include an electric field line that draws an arc. Therefore, the electric field in the first region Aa and the second region Ab depends on the thickness of the dielectric film 72. In the present example embodiment, by having the above-described configuration, the intensity of the electric field in the first region Aa and the intensity of the electric field in the second region Ab can be made different from each other in a case where the inclination of the crystal axis of the piezoelectric body layer 8 is not taken into consideration. In addition, as in the present example embodiment, in a case where the crystal axis of the piezoelectric body layer 8 is inclined, the intensity of the electric field in the first region Aa and the intensity of the electric field in the second region Ab can be brought close to each other. Therefore, the IMD can be reduced or prevented.

In addition, in the acoustic wave device 71, the thickness of a silicon oxide layer 72A is different between the first portion 72a and the second portion 72b. In the first portion 72a and the second portion 72b, the thicknesses of the silicon nitride layers 72B may be different from each other. In the first portion 72a and the second portion 72b, the thickness of at least one layer in the dielectric film 72 may be different.

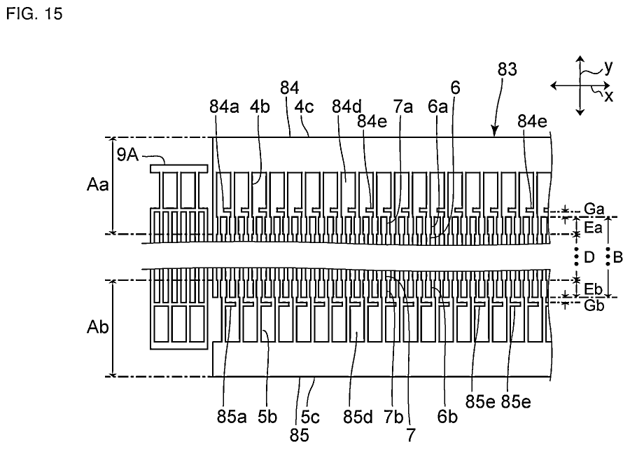

FIG. 14 is a schematic plan view showing an electrode structure of the IDT electrode of the ninth example embodiment near the first busbar, near the second busbar, and near one of the reflectors.

The present example embodiment is different from the first example embodiment in that an inner busbar portion 84a of the first busbar 84 of the IDT electrode 83 is cut into a plurality of portions and is discontinuous. The present example embodiment is different from the first example embodiment also in that the inner busbar portion 85a of the second busbar 85 is cut into a plurality of portions and is discontinuous. The acoustic wave device 81 of the present example embodiment preferably has the same configuration as the acoustic wave device 1 of the first example embodiment in other respects than the above.

More specifically, the inner busbar portion 84a of the first busbar 84 includes a plurality of bar portions 84e. Each of the bar portions 84e is connected to only one of the adjacent connection portions 4b. Therefore, the inner busbar portion 84a has a configuration in which the inner busbar portion 84a is cut between the connection portions 4b as viewed from the second direction y side. Therefore, each cavity 84d is not completely surrounded by the inner busbar portion 84a, the outer side portion busbar portion 4c, and the connection portions 4b. Each of the cavities 84d communicates with the first gap region Ga.

In the present example embodiment, the bar portion 84e of the first busbar 84 preferably extends only to one side in the first direction x from the end portion of the connection portion 4b. However, the bar portion 84e may extend to both sides from the end portion of the connection portion 4b in the first direction x.

Similarly, in the second busbar 85, the inner busbar portions 85a preferably includes a plurality of bar portions 85e. Each of the bar portions 85e is connected to only one of the adjacent connection portions 5b. Each of the cavities 85d communicates with the second gap region Gb. The bar portion 85e extends only to one side in the first direction x from the end portion of the connection portion 5b. However, the bar portion 85e may extend to both sides from the end portion of the connection portion 5b in the first direction x.

Also in the present example embodiment, as in the first example embodiment, the dimension of each of the connection portions 4b in the first busbar 4 along the first direction x and the dimension of each of the connection portions 5b in the second busbar 5 along the first direction x are preferably different from each other. As a result, the configuration of the first region Aa and the configuration of the second region Ab are asymmetric. In addition, the crystal axis of the piezoelectric body layer 8 is inclined in a second direction y with respect to the thickness direction of the piezoelectric body layer 8. As a result, the intensity of the electric field in the first region Aa and the intensity of the electric field in the second region Ab can be brought close to each other. Therefore, the IMD can be reduced or prevented.

Here, a dimension from the center of the connection portion 4b in the first direction x in the first busbar 84 to the distal end of the bar portion 84e connected to the connection portion 4b is defined as a center-to-distal end distance of the connection portion 4b and the bar portion 84e. Similarly, the dimension from the center of the connection portion 5b in the first direction x in the second busbar 85 to the distal end of the bar portion 85e connected to the connection portion 5b is defined as the center-to-distal end distance of the connection portion 5b and the bar portion 85e. In the acoustic wave device 81, the center-to-distal end distance between the connection portions 4b and the plurality of bar portions 84e in the first busbar 84 is the same as the center-to-distal end distance between the connection portions 5b and the plurality of bar portions 85e in the second busbar 85.

However, the center-to-distal end distance between the connection portions 4b and the plurality of bar portions 84e in the first busbar 84 and the center-to-distal end distance between the connection portions 5b and the plurality of bar portions 85e in the second busbar 85 may be different from each other. For example, in the modified example of the ninth example embodiment shown in FIG. 15, the widths of the connection portions are the same in the first busbar 84 and the second busbar 85, and the center-to-distal end distances are different from each other. As a result, the configuration of the first region Aa and the configuration of the second region Ab are asymmetric. In this case as well, the IMD can be reduced or prevented.

In the first to ninth example embodiments and each modified example described above, the configuration of the first region Aa and the configuration of the second region Ab are preferably asymmetric with each other by using one type of configuration. As described above, partial substitution or combination of the configurations is possible between the different example embodiments. That is, it is also possible to combine the configuration of the first example embodiment with the configuration of at least one of the second to ninth example embodiments or each modified example. The same applies to the second to ninth example embodiments and each modified example. Accordingly, the IMD can also be reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric body layer having a crystal axis; and
an interdigital transducer (IDT) electrode on the piezoelectric body layer; wherein
when an acoustic wave propagation direction is defined as a first direction and a direction orthogonal or substantially orthogonal to the first direction is defined as a second direction, the crystal axis of the piezoelectric body layer is inclined in the second direction with respect to a thickness direction of the piezoelectric body layer;
the IDT electrode includes one pair of busbars opposing each other and electrode fingers of which one end is connected to one of the pair of busbars, and among the electrode fingers, electrode fingers connected to one of the busbars and electrode fingers connected to another busbar are interdigitated to each other;
a region where the adjacent electrode fingers overlap each other in the first direction is a cross region, and the cross region includes a central region positioned on a central side in the second direction and one pair of edge regions that oppose each other with the central region interposed therebetween in the second direction;
when a dimension of the electrode finger along the first direction is defined as a width, each of the electrode fingers includes a wide portion positioned in the pair of edge regions;
the IDT electrode further includes one pair of gap regions positioned between the cross region and the pair of busbars;
each of the pair of busbars includes cavities located along the first direction, each of the pair of busbars includes an outer side portion busbar portion and an inner busbar portion that oppose each other with the cavities interposed therebetween in the second direction, and connection portions that connect the outer side portion busbar portion and the inner busbar portion in each of the pair of busbars, and the inner busbar portion is positioned closer to a cross region side than the outer side portion busbar portion; and
when a region defined by a region where the one of the busbars is provided, one of the gap regions, and one of the edge regions is defined as a first region, and a region defined by a region where the other busbar is provided, the other gap region, and the other edge region is defined as a second region, a configuration of the first region and a configuration of the second region are asymmetric.

2. The acoustic wave device according to claim 1, wherein a dimension of each of the connection portions along the first direction in the one of the busbars is different from a dimension of each of the connection portions along the first direction in the another busbar.

3. The acoustic wave device according to claim 1, wherein a dimension of the connection portions along the second direction in the one of the busbars is different from a dimension of the connection portions along the second direction in the another busbar.

4. The acoustic wave device according to claim 1, wherein a pitch between the connection portions in the one of the busbars is different from a pitch between the connection portions in the another busbar.

5. The acoustic wave device according to claim 1, wherein a dimension of the inner busbar portion along the second direction in the one of the busbars is different from a dimension of the inner busbar portion along the second direction in the another busbar.

6. The acoustic wave device according to claim 1, wherein a dimension of the one of the gap regions along the second direction is different from a dimension of the another gap region along the second direction.

7. The acoustic wave device according to claim 1, wherein, in the electrode fingers, a width of the wide portion in the one of the edge regions is different from a width of the wide portion in the another edge region.

8. The acoustic wave device according to claim 1, wherein, in the electrode fingers, a thickness of the wide portion in the one of the edge regions is different from a thickness of the wide portion in the another edge region.

9. The acoustic wave device according to claim 1, further comprising:
a dielectric film on the piezoelectric body layer and covering the IDT electrode; wherein
a thickness of a portion positioned in the one of the edge regions of the dielectric film is different from a thickness of a portion positioned in the another edge region of the dielectric film.

10. An acoustic wave device comprising:
a piezoelectric body layer having a crystal axis; and
an IDT electrode on the piezoelectric body layer; wherein
when an acoustic wave propagation direction is defined as a first direction and a direction orthogonal or substantially orthogonal to the first direction is defined as a second direction, the crystal axis of the piezoelectric body layer is inclined in the second direction with respect to a thickness direction of the piezoelectric body layer;
the IDT electrode includes one pair of busbars opposing each other, first electrode fingers each including one end connected to one of the busbars, and second electrode fingers each including one end connected to another busbar, and the first electrode fingers and the second electrode fingers are interdigitated to each other;
a region where the first electrode finger and the second electrode finger which are adjacent to each other overlap each other in the first direction is a cross region, and the cross region further includes a central region positioned on a central side in the second direction and one pair of edge regions that oppose each other with the central region interposed therebetween in the second direction;
when a dimension of the first electrode finger and the second electrode finger along the first direction is defined as a width, each of the first electrode fingers and the second electrode fingers includes a wide portion positioned in the pair of edge regions;
the IDT electrode further includes one pair of gap regions positioned between the cross region and the pair of busbars;
each of the pair of busbars includes cavities located along the first direction, each of the pair of busbars includes an outer side portion busbar portion and an inner busbar portion that oppose each other with the cavities interposed therebetween in the second direction, and connection portions that connect the outer side portion busbar portion and the inner busbar portion in each of the pair of busbars, and the inner busbar portion is positioned closer to a cross region side than the outer side portion busbar portion; and
when a region defined by a region where the one of the busbars is provided, one of the gap regions, and one of the edge regions is defined as a first region, and a region defined by a region where the other busbar is provided, the other gap region, and the other edge region is defined as a second region, an electrostatic capacitance formed by the connection portion, the inner busbar portion, at least some of the first electrode fingers, and the wide portion of the second electrode fingers in the first region, and an electrostatic capacitance defined by the connection portion, the inner busbar portion, at least some of the second electrode fingers, and the wide portion of the first electrode fingers in the second region are different from each other.

11. An acoustic wave device comprising:
a piezoelectric body layer having a crystal axis; and
an IDT electrode on the piezoelectric body layer; wherein
the IDT electrode includes one pair of busbars opposing each other and electrode fingers each including one end connected to any one of the pair of busbars, and among the electrode fingers, electrode fingers connected to one of the busbars and electrode fingers connected to another busbar are interdigitated to each other;
when directions orthogonal or substantially orthogonal to each other are defined as a first direction and a second direction, and the second direction is defined as the direction in which the electrode fingers extend, the crystal axis of the piezoelectric layer is inclined in the second direction with respect to a thickness direction of the piezoelectric body layer;
a region where ones of the electrode fingers adjacent to each other overlap each other in the first direction is a cross region, and the cross region includes a central region positioned on a central side in the second direction and one pair of edge regions that oppose each other with the central region interposed therebetween in the second direction;
when a dimension of the electrode finger along the first direction is defined as a width, each of the electrode fingers includes a wide portion positioned in the pair of edge regions;
the IDT electrode further includes one pair of gap regions positioned between the cross region and the pair of busbars;
each of the pair of busbars includes cavities located along the first direction, each of the pair of busbars includes an outer side portion busbar portion and an inner busbar portion that oppose each other with the cavities interposed therebetween in the second direction, and connection portions that connect the outer side portion busbar portion and the inner busbar portion, and the inner busbar portion is positioned closer to the cross region side than the outer side portion busbar portion;
a dielectric film covering the IDT electrode is further provided on the piezoelectric body layer; and
when a region defined by a region where the one of the busbars is provided, one of the gap regions, and one of the edge regions is defined as a first region, and a region defined by a region where the other busbar is provided, the other gap region, and the other edge region is defined as a second region, at least one of the following relationships 1) to 8) is different between the first region and the second region:
1) a dimension of each of the connection portions along the first direction in the one of the busbars and a dimension of each of the connection portions along the first direction in the other busbar;
2) a dimension of the connection portions along the second direction in the one of the busbars and a dimension of the connection portions along the second direction in the other busbar;
3) a pitch between the connection portions in the one of the busbars and a pitch between the connection portions in the other busbar;
4) a dimension of the inner busbar portion along the second direction in the one of the busbars and a dimension of the inner busbar portion along the second direction in the other busbar;
5) a dimension of the one of the gap regions along the second direction and a dimension of the other gap region along the second direction;
6) a width of the wide portion in the one of the edge regions and a width of the wide portion in the other edge region in the electrode fingers;
7) a thickness of the wide portion in the one of the edge regions and a thickness of the wide portion in the other edge region in the electrode fingers; and
8) a thickness of a portion positioned in the one of the edge regions of the dielectric film and a thickness of a portion positioned in the other edge region of the dielectric film.

12. The acoustic wave device according to claim 1, further comprising:
a pair of reflectors; wherein
the pair of reflectors and the IDT electrode are both provided on the piezoelectric body layer.

13. The acoustic wave device according to claim 1, wherein a width of the electrode finger in each wide portion is wider than a width of the electrode finger in the central region.

14. The acoustic wave device according to claim 1, wherein a dimension of the connection portions along the second direction in the one of the busbars is the same or substantially the same as a dimension of the connection portions along the second direction in the other busbar.

15. The acoustic wave device according to claim 1, further comprising a mass addition film on at least one of the wide portions of the electrode finger in one of the pair of edge regions.

16. The acoustic wave device according to claim 1, further comprising a mass addition film on at least one of the wide portions of the electrode finger in both of the pair of edge regions.

17. The acoustic wave device according to claim 1, wherein at least one of the inner busbar portions is cut into a plurality of portions and is discontinuous.
